(19) United States
(12) Patent Application Publication
(10) Pub. No.: US 2025/0212651 A1
(43) Pub. Date: Jun. 26, 2025

(54) DISPLAY DEVICE

(71) Applicant: LG Display Co., Ltd., Seoul (KR)

(72) Inventors: Heonkwang PARK, Paju-si (KR); Byungjun LIM, Paju-si (KR)

(73) Assignee: LG Display Co., Ltd., Seoul (KR)

(21) Appl. No.: 18/808,924

(22) Filed: Aug. 19, 2024

(30) Foreign Application Priority Data
Dec. 22, 2023 (KR) 10-2023-0189125

(51) Int. Cl. H10K 59/65; H10K 59/126; H10K 59/131; H10K 59/40; H10K 59/80

(52) U.S. Cl. CPC H10K 59/65; H10K 59/126; H10K 59/131; H10K 59/40; H10K 59/873

(57) ABSTRACT

A display device can include a substrate including a display area and a first non-display area and a second non-display area adjacent to the display area, an insulating layer located on the substrate, a plurality of first patterns located in the first non-display area on the insulating layer, a plurality of second patterns located in the second non-display area on the insulating layer, and a structure located between the plurality of second patterns. Additionally, the structure can include a first metal layer located between the substrate and the insulating layer, and a second metal layer located on the first metal layer. Further, the second metal layer can be connected to the first metal layer via a first opening disposed in the insulating layer.

### CROSS-REFERENCE TO RELATED APPLICATION

This application claims priority to Korean Patent Application No. 10-2023-0189125 filed on Dec. 22, 2023, in the Republic of Korea, the contents of which in its entirety are herein incorporated by reference.

### BACKGROUND

### 1. Field

The present disclosure relates to a display device.

### 2. Description of Related Art

As technology advances, a display device is being applied to various electronic devices, such as a TV, a mobile phone, a laptop, and a tablet, and transportation means. The display device is becoming thinner, lighter, and less power-consuming, and research for display devices are continuing. In addition, some of the display devices can include a built-in camera.

Specifically, the mobile phone can have a built-in camera, and the camera limits a screen design, making the screen design difficult. Accordingly, the mobile phone has a hole defined in a screen to create a space for the camera under the screen.

However, because of the hole in the screen, the display device, which is vulnerable to moisture and oxygen, is prone to deterioration. Accordingly, a method to prevent the moisture and the oxygen from penetrating along an end of the hole of the display device is needed.

### SUMMARY OF THE DISCLOSURE

An embodiment of the present disclosure provides a display device that can prevent a light emitting element from being damaged by moisture, oxygen, and the like penetrating from the outside via a hole in a display area of a display panel.

An embodiment of the present disclosure provides a display device that can prevent damage to a light emitting element by providing a structure that can block a crack from an outside in a non-display area.

However, purposes according to the present disclosure are not limited to the above-mentioned purposes. Other purposes and advantages according to the present disclosure that are not mentioned can be understood based on following descriptions, and can be more clearly understood based on embodiments according to the present disclosure. Further, it will be easily understood that the purposes and advantages according to the present disclosure can be realized using means shown in the claims or combinations thereof.

A display device according to an embodiment of the present disclosure can include a substrate including a display area, a first non-display area and a second non-display area located around the display area, an insulating layer located on the substrate, first patterns located in the first non-display area on the insulating layer, second patterns located in the second non-display area on the insulating layer, and a structure located between the second patterns, wherein the structure includes a first metal layer located between the substrate and the insulating layer, and a second metal layer located on the first metal layer, and the second metal layer is connected to the first metal layer via a first opening defined in the insulating layer.

According to the embodiment of the present disclosure, a moisture and oxygen penetrating toward the light emitting element along the organic material layer via a hole in the display area of the display panel can be blocked.

According to the embodiment of the present disclosure, a crack propagating toward the light emitting element can be prevented by providing the structure that can block the crack from the outside.

According to the embodiment of the present disclosure, the crack propagating from the outside can be effectively blocked via the structure in which one metal layer on the substrate is connected to another metal layer. Accordingly, the reliability and the lifespan of the display device can be improved and energy reduction and low-power operation of the production process can become available.

Effects of the present disclosure are not limited to the above-mentioned effects, and other effects as not mentioned will be clearly understood by those skilled in the art from following descriptions.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a plan view of a display device according to embodiments of the present disclosure.

FIG. 2 is an enlarged view of an area A in FIG. 1 according to embodiments of the present disclosure.

FIG. 3 is a cross-sectional view of a sub-pixel along a line I-I′ in FIG. 1 according to embodiments of the present disclosure.

FIG. 4 is a cross-sectional view taken along a line II-II′ in FIG. 2 according to an embodiment of the present disclosure.

FIG. 5 is an enlarged view of an area B in FIG. 4 according to an embodiment of the present disclosure.

FIG. 6 is a cross-sectional view taken along a line II-II′ in FIG. 2 according to another embodiment of the present disclosure.

FIG. 7 is an enlarged view of an area C in FIG. 6 according to another embodiment of the present disclosure.

FIG. 8 is a cross-sectional view taken along a line II-II′ in FIG. 2 according to another embodiment of the present disclosure.

FIG. 9 is an enlarged view of an area D in FIG. 8 according to another embodiment of the present disclosure.

### DETAILED DESCRIPTION OF THE EMBODIMENTS

Advantages and features of the present disclosure, and a method of achieving the advantages and features will become apparent with reference to embodiments described later in detail together with the accompanying drawings. However, the present disclosure is not limited to the embodiments as disclosed under, but can be implemented in various different forms. Thus, these embodiments are set forth only to make the present disclosure complete, and to completely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure can be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as can be included within the spirit and scope of the present disclosure as defined by the appended claims.

A shape, a size, a ratio, an angle, a number, etc. disclosed in the drawings for illustrating embodiments of the present disclosure are illustrative, and the present disclosure is not limited thereto.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements can modify the entire list of elements and does not modify the individual elements of the list. In interpretation of numerical values, an error or tolerance therein can occur even when there is no explicit description thereof.

In addition, it will also be understood that when a first element or layer is referred to as being present “on” a second element or layer, the first element or layer can be disposed directly on the second element or layer, or can be disposed indirectly on the second element or layer with a third element or layer being disposed between the first and second elements or layers.

It will be understood that when an element or layer is referred to as being “connected to”, or “connected to” another element or layer, it can be directly on, connected to, or connected to the other element or layer, or one or more intervening elements or layers can be present. In addition, it will also be understood that when an element or layer is referred to as being “between” two elements or layers, it can be the only element or layer between the two elements or layers, or one or more intervening elements or layers can also be present.

Further, as used herein, when a layer, film, region, plate, or the like is disposed “on” or “on a top” of another layer, film, region, plate, or the like, the former can directly contact the latter or still another layer, film, region, plate, or the like is disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like can be disposed “below” or “under” another layer, film, region, plate, or the like, the former can directly contact the latter or still another layer, film, region, plate, or the like can be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event can occur therebetween unless “directly after”, “directly subsequent” or “directly before” is indicated.

When a certain embodiment can be implemented differently, a function or an operation specified in a specific block can occur in a different order from an order specified in a flowchart. For example, two blocks in succession can be actually performed substantially concurrently, or the two blocks can be performed in a reverse order depending on a function or operation involved.

It will be understood that, although the terms “first”, “second”, “third”, and so on can be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer, or section described below could be termed a second element, component, region, layer, or section, without departing from the spirit and scope of the present disclosure.

The features of the various embodiments of the present disclosure can be partially or entirely combined with each other, and can be technically associated with each other or operate with each other. The embodiments can be implemented independently of each other and can be implemented together in an association relationship.

In interpreting a numerical value, the value is interpreted as including an error range unless there is separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, and the like should not be construed such that any aspect or design as described is superior to or advantageous over other aspects or designs.

Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description below have been selected as being general and universal in the related technical field. However, there can be other terms than the terms depending on the development and/or change of technology, convention, preference of technicians, etc. Therefore, the terms used in the description below should not be understood as limiting technical ideas, but should be understood as examples of the terms for illustrating embodiments. Further, the term “can” encompasses all the meanings and coverages of the term “may.” The term “disclosure” is interchangeably used with, or encompasses all the meanings and coverages of, the term “invention.”

Further, in a specific case, a term can be arbitrarily selected by the applicant, and in this case, the detailed meaning thereof will be described in a corresponding description section. Therefore, the terms used in the description below should be understood based on not simply the name of the terms, but the meaning of the terms and the contents throughout the Detailed Descriptions. In addition, all the components of each display device according to all embodiments of the present disclosure are operatively coupled and configured.

Hereinafter, various embodiments of the present disclosure will be described in detail with reference to the attached drawings.

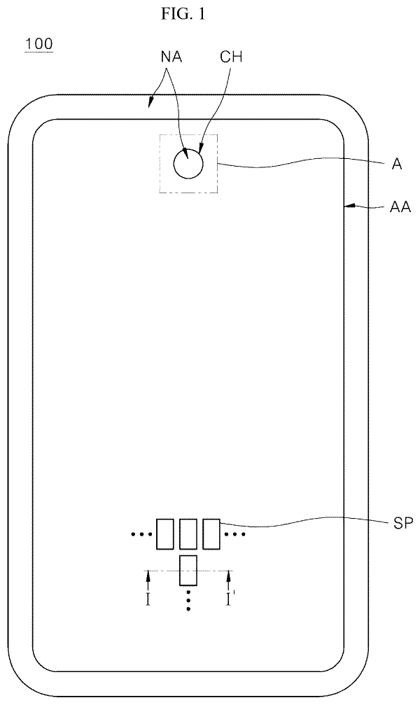

FIG. 1 is a plan view of a display device according to embodiments of the present disclosure.

Referring to FIG. 1, a display device 100 can include an optical module and a display panel. For example, the optical module can include a sensor, a camera, and the like, but embodiments of the present disclosure is not limited thereto.

The display panel can include a display area AA and a non-display area NA. The display area AA can be an area where an image is displayed. For example, the display area AA can be an active area, but the embodiments of the present disclosure is not limited thereto. The non-display area NA can be on the periphery of the display area AA or can surround the display area AA. In addition, the display panel can include more than one non-display area NA. For example, the non-display area NA can be a non-active area or a bezel area, but the embodiments of the present disclosure is not limited thereto.

The display area AA within the display device 100 can include a plurality of sub-pixels SP. The sub-pixel SP can include a pixel circuit composed of a switching transistor, a driving transistor, an organic light emitting diode, and the like.

The display device 100 according to an embodiment of the present disclosure can be an organic light emitting diode (OLED) display, a quantum dot (QD) display, a micro light emitting diode (micro LED) display, and the like, but the embodiments of the present disclosure is not limited thereto.

A hole CH can be disposed inside the display area AA of the display panel. For example, an optical module can be disposed to correspond to the hole CH. For example, the optical module can be a distance detection sensor, a facial recognition sensor, or the like, but the embodiments of the present disclosure is not limited thereto.

Additionally, because the optical module can be disposed under the hole CH, the non-display area NA can be reduced, and the display area AA can be enlarged or widened. A product with the enlarged display area AA can improve screen immersion of a user. For example, rather than have the optical module disposed at the non-display area along an edge of the display area AA, the optical module can be disposed inside the hole CH.

Further, there can be the single hole CH as shown, but the embodiments of the present disclosure is not limited thereto. For example, the number and a shape of holes CH can vary. For example, two or more holes CH can be disposed inside the display area AA, and the camera can be disposed inside the first hole and the sensors such as the distance detection sensor or the facial recognition sensor can be disposed inside the second hole, but the embodiments of the present disclosure is not limited thereto. The hole CH can be a through-hole, but the embodiments of the present disclosure is not limited thereto. Additionally, the two or more holes CH can be disposed adjacent to each other, or on opposite sides of the display area AA from each other. In an embodiment, the two or more holes can be disposed close to an edge of the display area AA, however the embodiments of the present disclosure is not limited thereto. Further, each of the two or more holes can have a different size from the other respective hole.

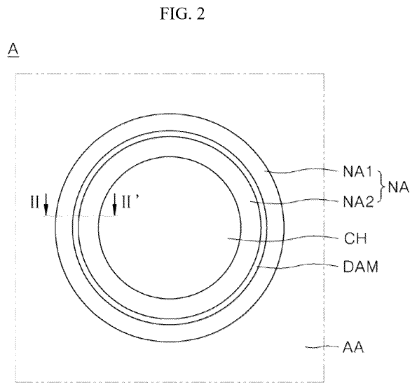

FIG. 2 is an enlarged view of an area A in FIG. 1 according to embodiments of the present disclosure.

Referring to FIG. 2, the area A can include a portion of the display area AA, the non-display area NA, and the hole CH.

The non-display area NA can include a first non-display area NA1 adjacent to the display area AA and a second non-display area NA2 adjacent to the hole CH. For example, the first non-display area NA1 can be located outside the second non-display area NA2. Additionally, the second non-display area NA2 can be located closer to the hole CH than the first non-display area NA1. However, in another embodiment, the second non-display area NA2 can be located outside the first non-display area NA1.

The first non-display area NA1 can include a dam DAM. For example, the dam DAM and the hole CH can be disposed to be spaced apart from each other, but the present disclosure is not limited thereto. Further, the dam DAM can be disposed to surround the hole CH. Additionally, the dam DAM can entirely surround the hole CH, or only surround a portion of the hole CH.

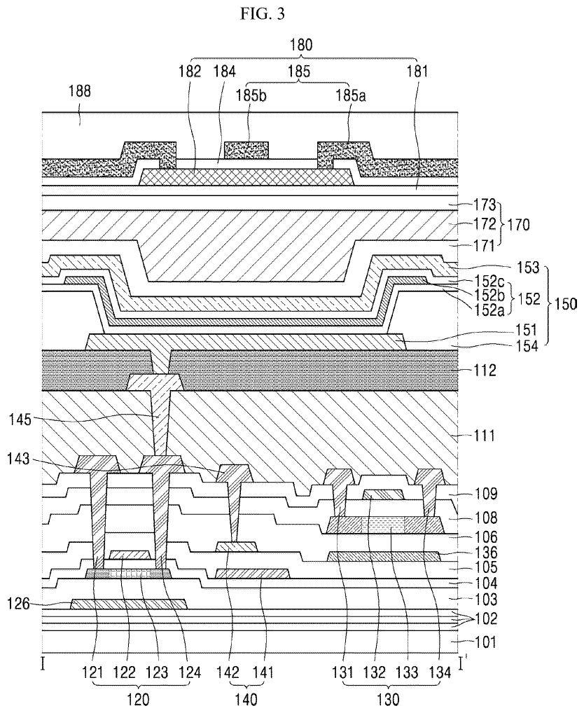

FIG. 3 is a cross-sectional view of a sub-pixel along a line I-I′ in FIG. 1 according to an embodiment of the present disclosure.

Referring to FIGS. 1 and 3, the display device 100 can include a substrate 101, a buffer layer 102, a first thin film transistor (TFT) 120, a second thin film transistor (TFT) 130, a storage capacitor 140, and a light emitting element 150, an encapsulation portion 170, and a touch unit 180.

The substrate 101 can include one or more plastic materials. For example, the substrate 101 can be a multi-substrate including a plurality of plastic materials such as polyimide, but the present disclosure is not limited thereto.

The buffer layer 102 can be disposed on the substrate 101. The buffer layer 102 can minimize or delay diffusion of moisture or oxygen from penetrating into the substrate 101. The buffer layer 102 can be formed by alternately depositing silicon nitride (SiNx) and silicon oxide (SiOx) at least once, but the embodiments of the present disclosure is not limited thereto.

A first light blocking layer 126 can be disposed on the buffer layer 102. The first light blocking layer 126 can prevent light from being incident on a first semiconductor layer 123 of the first thin film transistor 120. For example, the first semiconductor layer 123 can be formed to overlap the first light blocking layer 126. The first light blocking layer 126 can be formed of a single layer or multiple layers. The first light blocking layer 126 can include molybdenum (Mo), aluminum (Al), chromium (Cr), nickel (Ni), neodymium (Nd), and copper (Cu), or an alloy thereof, but the present disclosure is not limited thereto.

A first insulating layer 103 can be disposed on the first light blocking layer 126. The first insulating layer 103 can prevent short circuit between a component of the first thin film transistor 120 and the first light blocking layer 126. Additionally, the first insulating layer 103 can be disposed between the first thin film transistor 120 and the first light blocking layer 126.

The first insulating layer 103 can be made of the same material as the buffer layer 102, but the embodiments of the present disclosure is not limited thereto. For example, the first insulating layer 103 can be made of an inorganic material such as silicon nitride (SiNx) and silicon oxide (SiOx), but the present disclosure is not limited thereto.

The first thin film transistor 120 can be disposed on the first insulating layer 103. The first thin film transistor 120 can include a first source electrode 121, a first gate electrode 122, the first semiconductor layer 123, and a first drain electrode 124.

The first semiconductor layer 123 of the first thin film transistor 120 can be disposed on the first insulating layer 103. The first semiconductor layer 123 can include a metal oxide semiconductor, such as indium-gallium-zinc oxide (IGZO), a silicon-based semiconductor material, such as amorphous silicon or polycrystalline silicon, but the present disclosure is not limited thereto. Further, the first semiconductor layer 123 can include a channel area, a source area, and a drain area.

A polycrystalline semiconductor layer has higher mobility than an amorphous semiconductor layer and an oxide semiconductor. Accordingly, when a polycrystalline semiconductor is implemented, the thin film transistor can have low energy consumption and improved reliability. Therefore, when the first thin film transistor 120 is a driving transistor, the semiconductor layer 123 of the first thin film transistor 120 can be formed as the polycrystalline semiconductor layer.

A second insulating layer 104 can be disposed on the first semiconductor layer 123. The second insulating layer 104 can be made of the same material as the first insulating layer 103 and can prevent short circuit between the first semiconductor layer 123 and another component of the first thin film transistor 120. However, in another embodiment, the second insulating layer 104 can be formed of a different insulating material than the first insulating layer 103.

The first gate electrode 122 can be disposed on the second insulating layer 104. The first gate electrode 122 can be disposed on the second insulating layer 104 to overlap the channel area of the first semiconductor layer 123. The first gate electrode 122 can be disposed of a single layer or multiple layers. Additionally, the first semiconductor layer 123 can include molybdenum (Mo), copper (Cu), titanium (Ti), aluminum (Al), chromium (Cr), gold (Au), nickel (Ni), and neodymium (Nd), or an alloy thereof. Further, the first gate electrode 122 can be formed together with a gate line.

A third insulating layer 105 can be disposed on the first gate electrode 122. The third insulating layer 105 can be made of the same material as the first insulating layer 103 or the second insulating layer 104. However, in another embodiment, the third insulating layer 105 can be formed of a different insulating material than the first insulating layer 103, and the second insulating layer 104.

The storage capacitor 140 can be disposed to be spaced apart from the first thin film transistor 120. The storage capacitor 140 can include a first storage electrode 141 and a second storage electrode 142.

The first storage electrode 141 can be disposed on the same layer as the first gate electrode 122 and can be made of the same material as the first gate electrode 122, but the present disclosure is not limited thereto.

The second storage electrode 142 can be disposed on the third insulating layer 105 and overlap the first storage electrode 141. Additionally, the second storage electrode 142 can have a longer length than the first storage electrode.

The second storage electrode 142 can be made of the same material as the first storage electrode 141, but the present disclosure is not limited thereto.

The second thin film transistor 130 can be disposed to be spaced apart from the first thin film transistor 120 and the storage capacitor 140. Additionally, the storage capacitor 140 can be disposed between the first thin film transistor 120 and the second thin film transistor 130, but the present disclosure is not limited thereto. For example, the storage capacitor 140 can be disposed not between the first thin film transistor 120 and the second thin film transistor 130 such that the first thin film transistor 120 and the second thin film transistor 130 are adjacent to each other.

The second thin film transistor 130 can include a second source electrode 131, a second gate electrode 132, a second semiconductor layer 133, and a second drain electrode 134.

A second light blocking layer 136 can be disposed at the same layer as the second storage electrode 142.

The second light blocking layer 136 can prevent light directed to the second semiconductor layer 133 from reaching the second semiconductor layer 133, similarly to the first light blocking layer 126, thereby extending a lifespan of the second thin film transistor 130. For example, the second semiconductor layer 133 can be disposed to overlap the second light blocking layer 136.

A fourth insulating layer 106 can be disposed on the second light blocking layer 136. The fourth insulating layer 106 can be made of the same material as the first insulating layer 103, second insulating layer 104, or third insulating layer 105, but the present disclosure is not limited thereto. For example, in another embodiment, the fourth insulating layer 106 can be formed of a different insulating material than the first insulating layer 103, the second insulating layer 104, and the third insulating layer 105.

The second semiconductor layer 133 can be disposed on the fourth insulating layer 106. The second semiconductor layer 133 can include a source area, a drain area, and a channel area between the source area and the drain area.

The second semiconductor layer 133 can include a metal oxide semiconductor, such as indium-gallium-zinc oxide (IGZO), a silicon-based semiconductor material, such as amorphous silicon or polycrystalline silicon, but the present disclosure is not limited thereto.

A fifth insulating layer 108 can be formed on the second semiconductor layer 133. The fifth insulating layer 108 can be made of the same material as the first insulating layer 103, the second insulating layer 104, the third insulating layer 105, or the fourth insulating layer 106, but the present disclosure is not limited thereto. For example, in another embodiment, the fifth insulating layer 108 can be formed of a different insulating material than the first insulating layer 103, the second insulating layer 104, the third insulating layer 105, and the fourth insulating layer 106.

The second gate electrode 132 can be disposed on the fifth insulating layer 108.

The second gate electrode 132 can be made of the same material as the first gate electrode 122. For example, the second gate electrode 132 can be formed of a single layer or multiple layers including molybdenum (Mo), copper (Cu), titanium (Ti), aluminum (Al), chromium (Cr), gold (Au), nickel (Ni), and neodymium (Nd), or an alloy thereof, but the present disclosure is not limited thereto.

A sixth insulating layer 109 can be formed on the second gate electrode 132. The sixth insulating layer 109 can be made of the same material as the first insulating layer 103, the second insulating layer 104, the third insulating layer 105, the fourth insulating layer 106, or the fifth insulating layer 108, but the present disclosure is not limited thereto. For example, in another embodiment, the sixth insulating layer 109 can be formed of a different insulating material than the first insulating layer 103, the second insulating layer 104, the third insulating layer 105, the fourth insulating layer 106, and the fifth insulating layer 108.

The first source electrode 121, the first drain electrode 124, a storage connection electrode 143, the second source electrode 131, and the second drain electrode 134 can be disposed on the sixth insulating layer 109. The first source electrode 121 and the first drain electrode 124 can be electrically connected to the first semiconductor layer 123 via a contact hole formed in the second to sixth insulating layers 104, 105, 106, 108, and 109. The second source electrode 131 and the second drain electrode 134 can be electrically connected to the second semiconductor layer 133 via a contact hole formed in the fifth and sixth insulating layers 108 and 109. The storage connection electrode 143 can be electrically connected to the second storage electrode 142 via a contact hole formed in the fourth to sixth insulating layers 106, 108, and 109.

The first source electrode 121, the first drain electrode 124, the storage connection electrode 143, the second source electrode 131, and the second drain electrode 134 can be made of the same material and can be disposed at the same layer. For example, the first source electrode 121, the first drain electrode 124, the storage connection electrode 143, the second source electrode 131, and the second drain electrode 134 can be disposed of a single layer or multiple layers. Additionally, the first source electrode 121, the first drain electrode 124, the storage connection electrode 143, the second source electrode 131, and the second drain electrode 134 can include molybdenum (Mo), aluminum (Al), chromium (Cr), gold (Au), titanium (Ti), nickel (Ni), neodymium (Nd), and copper (Cu), or an alloy thereof, but the present disclosure is not limited thereto. The first source electrode 121, the first drain electrode 124, the storage connection electrode 143, the second source electrode 131, and the second drain electrode 134 can be, for example, formed of triple layers such as Ti/Al/Ti.

The first thin film transistor 120 can be the driving transistor and the second thin film transistor 130 can be a switching transistor, but the present disclosure is not limited thereto.

A first protective layer 111 can be disposed on the first source electrode 121, the first drain electrode 124, the storage connection electrode 143, the second source electrode 131, and the second drain electrode 134.

The first protective layer 111 can provide a flat surface by covering steps caused by the first thin film transistor 120 and the second thin film transistor 130 and protect the first thin film transistor 120 and the second thin film transistor 130. The first protective layer 111 can be made of an organic material. For example, the first protective layer 111 can be made of the organic material including acrylic resin, epoxy resin, phenolic resin, polyamide resin, or polyimide resin, but the present disclosure is not limited thereto.

A second protective layer 112 can be disposed on the first protective layer 111. The second protective layer 112 can be made of the same material as the first protective layer 111, but the present disclosure is not limited thereto.

A connection electrode 145 can be formed between the first protective layer 111 and the second protective layer 112.

The connection electrode 145 can electrically connect the first thin film transistor 120 with the light emitting element 150. The connection electrode 145 can be made of the same material as the first source electrode 121 and the first drain electrode 124, but the present disclosure is not limited thereto. The connection electrode 145 can be, for example, formed of triple layers such as Ti/Al/Ti.

A thickness of the connection electrode 145 can be greater than a thickness of the first gate electrode 122 of the first thin film transistor 120 and a thickness of the second gate electrode 132 of the second thin film transistor 130.

The light emitting element 150 can be disposed on the second protective layer 112.

The light emitting element 150 can include an anode electrode 151, a light emitting layer 152, and a cathode electrode 153.

The anode electrode 151 can be disposed on the second protective layer 112. Additionally, the anode electrode 151 can have a shorter length than the second protective layer 112.

The anode electrode 151 can be electrically connected to the connection electrode 145 via a contact hole formed in the second protective layer 112. The anode electrode 151 can be electrically connected to the first thin film transistor 120 via the connection electrode 145.

The anode electrode 151 can be a reflective electrode that reflects light, but the present disclosure is not limited thereto.

The anode electrode 151 can include a metal material with high reflectivity such as a stacked structure (Ti/Al/Ti) of aluminum (Al) and titanium (Ti), a stacked structure (ITO/Al/ITO) of aluminum (Al) and ITO, and an APC alloy and can be formed of a single layer or multiple layers, but the present disclosure is not limited thereto.

The light emitting layer 152 can be disposed on the anode electrode 151. The light emitting layer 152 can include one or more light emitting structures (or light emitting elements) on the anode electrode 151.

The light emitting layer 152 can include a first light emitting auxiliary layer 152a, a light emitting material layer 152b, and a second light emitting auxiliary layer 152c. Additionally, the first light emitting auxiliary layer 152a can include a hole injection layer and a hole transfer layer, but the present disclosure is not limited thereto. Further, the second light emitting auxiliary layer 152c can include an electron injection layer and an electron transfer layer, but the present disclosure is not limited thereto. In addition, the hole transfer layer can include a hole transport layer, a hole injection layer, an electron blocking layer, a P-type charge generation layer, and the like, but the embodiments of the present disclosure is not limited thereto. Further, the electron transfer layer can include an electron transport layer, an electron injection layer, a hole blocking layer, an N-type charge generation layer, and the like, but the embodiments of the present disclosure is not limited thereto.

The first light emitting auxiliary layer 152a and the second light emitting auxiliary layer 152c can be an organic material layer, an organic substance layer, a charge transfer layer, or a light emitting auxiliary layer, but the present disclosure is not limited thereto.

The light emitting layer 152 can include an organic light emitting material layer, an inorganic light emitting material layer, a quantum dot light emitting material layer, a micro light emitting diode, a mini light emitting diode, or the like, but the present disclosure is not limited thereto. For example, the light emitting material layer 152b of the display device 100 according to an embodiment of the present disclosure can include the organic light emitting material layer.

The light emitting layer 152 can include a red light emitting layer, a green light emitting layer, and a blue light emitting layer. For example, the light emitting material layer 152b can include the red light emitting material layer, the green light emitting material layer, and the blue light emitting material layer.

In another embodiment, the light emitting layer 152 can include a red light emitting layer, a green light emitting layer, a blue light emitting layer, and a white light emitting layer. Additionally, the light emitting material layer 152b can include the red light emitting material layer, the green light emitting material layer, the blue light emitting material layer, and the white light emitting layer.

The cathode electrode 153 can be disposed on the light emitting layer 152. The cathode electrode 153 can be a transparent electrode that transmits light, but the present disclosure is not limited thereto. For example, the cathode electrode 153 can include a transparent conductive material, such as indium tin oxide (ITO) or indium zinc oxide (IZO), or a metal that transmits visible light, but the present disclosure is not limited thereto.

A bank 154 can be disposed to expose the anode electrode 151. The bank 154 can define an opening (or a light emitting area) of the sub-pixel and can be disposed to cover an edge of the anode electrode 151. Each sub-pixel can include a red light emitting area, a green light emitting area, and a blue light emitting area. Additionally, in another embodiment, each sub-pixel can include a red light emitting area, a green light emitting area, a blue light emitting area, and a white light emitting area. For example, the light emitting material layer 152b can be partitioned by the bank 154. For example, the light emitting material layer 152b can extend to a side surface of the bank 154, but the present disclosure is not limited thereto. In addition, the anode electrode 151 can be disposed between adjacent banks 154.

The encapsulation portion 170 can be disposed on the bank 154 or the light emitting element 150. The encapsulation portion 170 can include one or more insulating layers. For example, the encapsulation portion 170 can include a first encapsulation layer 171, a second encapsulation layer 172 disposed on the first encapsulation layer 171, and a third encapsulation layer 173 disposed on the second encapsulation layer 172. The encapsulation portion 170 can include one or more inorganic material layers and one or more organic material layers. For example, the first encapsulation layer 171 and the third encapsulation layer 173 can include an inorganic material and the second encapsulation layer 172 can include an organic material, but the present disclosure is not limited thereto.

The touch unit 180 can include a touch buffer layer 181, a bridge electrode 182, a touch insulating layer 184, and touch electrode 185. The touch buffer layer 181 can be disposed on the encapsulation portion 170. For example, the touch buffer layer 181 can be disposed on the third encapsulation layer 173.

The touch buffer layer 181 can be made of the same material as the buffer layer 102. The touch insulating layer 184 can be disposed on the touch buffer layer 181. The touch insulating layer 184 can prevent short circuit between touch electrodes. The touch insulating layer 184 can be made of silicon oxide (SiOx) or silicon nitride (SiNx) or formed of multiple layers thereof, but the present disclosure is not limited thereto.

The touch electrode 185 can be disposed on the touch insulating layer 184. The touch electrode 185 can include a first touch electrode 185a extending in a first direction and a second touch electrode 185b extending in a second direction different from the first direction.

The bridge electrode 182 can be disposed between the touch buffer layer 181 and the touch insulating layer 184. The first touch electrode 185a can be electrically connected to the bridge electrode 182 via a contact hole formed in the touch insulating layer 184. For example, the first touch electrode 185a and the bridge electrode 182 can extend in the first direction.

The touch electrode 185 and the bridge electrode 182 can include a metal material. For example, the touch electrode 185 and the bridge electrode 182 can be made of titanium (Ti), nickel (Ni), and aluminum (Al), or an alloy thereof, and can be formed of triple layers such as titanium (Ti)/aluminum (Al)/titanium (Ti), but the present disclosure is not limited thereto.

A touch protective layer 188 covering the touch electrode 185 and the bridge electrode 182 can be disposed on the touch insulating layer 184. The touch protective layer 188 can include an organic material, but is not limited thereto.

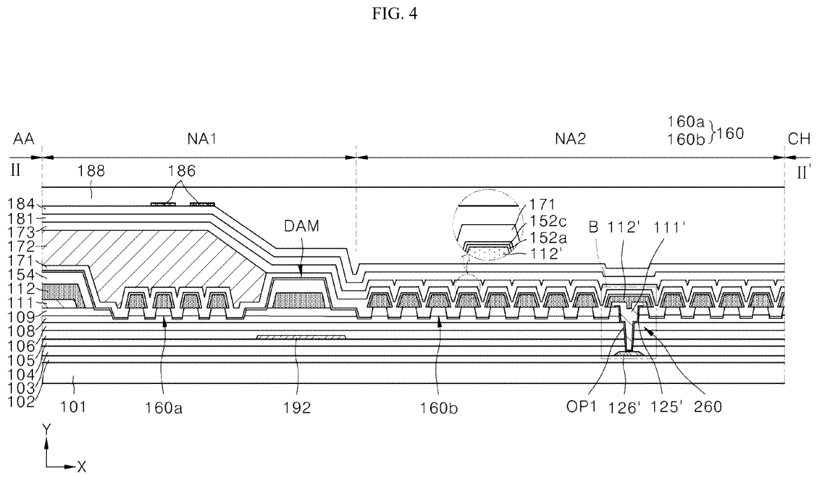

FIG. 4 is a cross-sectional view taken along a line II-II' in FIG. 2 according to an embodiment of the present disclosure.

Some of components shown in FIG. 4 can be formed by extending the components of the display area AA shown in FIG. 3 to the non-display area NA, and can be substantially the same as such components.

Hereinafter, the components that are substantially the same as those in FIG. 3 will be given the same reference numerals and redundant descriptions thereof will be omitted. Further, portions different from those in FIG. 3 will be described.

Referring to FIGS. 1 to 4, the display device 100 according to an embodiment of the present disclosure can include the display area AA, the non-display area NA, and the hole CH. The display device 100 can increase the screen immersion by maximizing the display area AA by disposing the hole CH inside the display area AA, but ends of the first light emitting auxiliary layer 152a and the second light emitting auxiliary layer 152c can be exposed in the process of forming the hole CH. In this regard, the first light emitting auxiliary layer 152a and the second light emitting auxiliary layer 152c can be formed by extending the first light emitting auxiliary layer 152a and the second light emitting auxiliary layer 152c of the display area AA to the non-display area NA. For example, a portion of the light emitting layer 152 can extend to the non-display area NA.

Additionally, in another embodiment with more than one hole CH, ends of the first light emitting auxiliary layer 152a and the second light emitting auxiliary layer 152c can be exposed in the process of forming the more than one hole CH. Accordingly, the first light emitting auxiliary layer 152a and the second light emitting auxiliary layer 152c can be formed by extending the first light emitting auxiliary layer 152a and the second light emitting auxiliary layer 152c of the display area AA to the non-display area NA in an area near each hole CH.

Accordingly, a moisture penetration path can be formed from the ends of the first light emitting auxiliary layer 152a and the second light emitting auxiliary layer 152c exposed via the hole CH to the light emitting element 150 of the display area AA. The display device 100 according to an embodiment of the present disclosure can provide a disconnecting structure of the first light emitting auxiliary layer 152a and the second light emitting auxiliary layer 152c or the like, thereby blocking the moisture, the oxygen, foreign substances, and the like that can move along the moisture penetration path. For example, the display device 100 can include patterns 160 arranged in the non-display area NA. The patterns 160 can disconnect the first light emitting auxiliary layer 152a and the second light emitting auxiliary layer 152c in the non-display area NA. The dam DAM can be disposed in the first non-display area NA1.

The dam DAM can include the same material as the second protective layer 112 and the bank 154 and only one dam DAM can be disposed to reduce the non-display area NA, but the present disclosure is not limited thereto. Additionally, the first light emitting auxiliary layer 152a and the second light emitting auxiliary layer 152c can be disposed to cover the dam DAM. The dam DAM can more effectively prevent the moisture and oxygen penetration by increasing a length of the moisture and oxygen penetration path.

To delay and block the penetration of the moisture from the outside via the exposed ends of the first light emitting auxiliary layer 152a and the second light emitting auxiliary layer 152c and to prevent damage to the display device 100 by the foreign substances, the patterns 160 can be disposed throughout the first non-display area NA1 and the second non-display area NA2. The patterns 160 can include first patterns 160a disposed to be spaced apart from each other in the first non-display area NA1 and second patterns 160b disposed to be spaced apart from each other in the second non-display area NA2. The dam DAM can be disposed between the first patterns 160a and the second patterns 160b.

Each pattern 160 can include the sixth insulating layer 109. Each pattern 160 can further include a support layer disposed on the sixth insulating layer 109. The support layer can include only a second support layer 112′ or can include a first support layer 111′ and the second support layer 112′. The sixth insulating layer 109 disposed on the pattern 160 can be a lower layer and the support layer of the pattern 160 can be an upper layer, disposed on the sixth insulating layer 109. For example, the pattern 160 can include at least one insulating layer.

The first support layer 111′ can be disposed at the same layer as and can be include the same material as the first protective layer 111 in the display area AA, but the embodiments of the present disclosure is not limited thereto. For example, the first support layer 111′ can be made of an organic material, but the embodiments of the present disclosure is not limited thereto.

The second support layer 112′ can be disposed on the sixth insulating layer 109 or the first support layer 111′. The second support layer 112′ can be disposed at the same layer as and include the same material as the second protective layer 112 in the display area AA, but the embodiments of the present disclosure is not limited thereto. For example, the second support layer 112′ can be made of an organic material, but the embodiments of the present disclosure is not limited thereto.

The first light emitting auxiliary layer 152a and the second light emitting auxiliary layer 152c can be disposed on the patterns 160. The first light emitting auxiliary layer 152a and the second light emitting auxiliary layer 152c can be formed on the support layer. The support layer can have predetermined height and width, and the first light emitting auxiliary layer 152a and the second light emitting auxiliary layer 152c can be disconnected depending on the height and the width of the support layer. For example, portions of the first light emitting auxiliary layer 152a and the second light emitting auxiliary layer 152c on the support layer can be disposed to be spaced apart from portions of the first light emitting auxiliary layer 152a and the second light emitting auxiliary layer 152c on the fifth insulating layer 108. For example, the portions of the first light emitting auxiliary layer 152a and the second light emitting auxiliary layer 152c on the fifth insulating layer 108 can be in contact with the fifth insulating layer 108.

The second patterns 160b can be disposed in the second non-display area NA2. A structure 260 can be disposed between the second patterns 160b. Hereinafter, a detailed configuration of the structure 260 will be described.

A first metal layer 126′ can be formed on the substrate 101. The first metal layer 126′ can be disposed between the dam DAM and the hole CH. The first metal layer 126′ can be formed at the same layer as the first light blocking layer 126 in the display area AA and can include the same material as the first light blocking layer 126, but the present disclosure is not limited thereto.

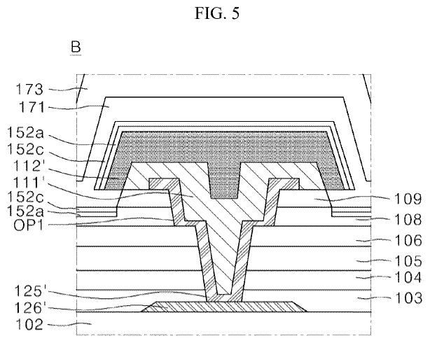

Referring to FIGS. 4 and 5, the first insulating layer 103 can be disposed on the first metal layer 126′. The second insulating layer 104 can be disposed on the first insulating layer 103. The third insulating layer 105 can be disposed on the second insulating layer 104. The fourth insulating layer 106 can be disposed on the third insulating layer 105. The fifth insulating layer 108 can be disposed on the fourth insulating layer 106. The sixth insulating layer 109 can be disposed on the fifth insulating layer 108.

The first insulating layer 103, the second insulating layer 104, the third insulating layer 105, the fourth insulating layer 106, the fifth insulating layer 108, and the sixth insulating layer 109 can include a first opening OP1. The first opening OP1 can be disposed between the dam DAM and the hole CH. The first opening OP1 can be disposed to surround the hole CH. In an embodiment, the first opening OP1 can be disposed closer to the hole CH than the dam DAM, but the present disclosure is not limited thereto. For example, in another embodiment, the first opening OP1 can be disposed closer to the dam DAM than the hole CH.

The first opening OP1 can be disposed to overlap the first metal layer 126′.

A second metal layer 125′ can be disposed on the sixth insulating layer 109. The second metal layer 125′ can be disposed between the dam DAM and the hole CH.

The second metal layer 125′ can be connected to the first metal layer 126′ via the first opening OP1. For example, the first metal layer 126′ can be in contact with the second metal layer 125′ within the first opening OP1. For example, the first metal layer 126′ can be in contact with the second metal layer 125′ can be in contact with each other at a lower end of the first opening OP1.

The second metal layer 125′ can be disposed at the same layer as the first source electrode 121 or the first drain electrode 124 in the display area AA and can include the same material as the first source electrode 121 or the first drain electrode 124, but the present disclosure is not limited thereto.

The structure 260 can include the first metal layer 126′ and the second metal layer 125′ that is connected to the first metal layer 126′ via the first opening OP1 extending through the first to sixth insulating layers 103, 104, 105, 106, 108, and 109. The structure 260 can be disposed to surround the hole CH. In an embodiment, the structure 260 can entirely surround the hole CH. However, in another embodiment, the structure 260 can only partially surround the hole CH. In addition, in an embodiment with more than one hole CH, the structure 260 can surround each hole CH.

The first encapsulation layer 171 and the third encapsulation layer 173 can be disposed throughout the display area AA and the non-display area NA. The first encapsulation layer 171 and the third encapsulation layer 173 can cover the patterns 160 and the structure 260.

The touch buffer layer 181 can be disposed on the third encapsulation layer 173 throughout the display area AA and the non-display area NA. For example, the touch buffer layer 181 can be disposed on the third encapsulation layer 173 throughout the first non-display area NA1 and the second non-display area NA2.

The touch insulating layer 184 can be disposed on the touch buffer layer 181 throughout the display area AA and the non-display area NA. For example, the touch insulating layer 184 can be disposed on the touch buffer layer 181 throughout the first non-display area NA1 and the second non-display area NA2. A third metal layer 186 can be disposed on the touch insulating layer 184. For example, the third metal layer 186 can be disposed in the non-display area NA. For example, the third metal layer 186 can be disposed in the first non-display area NA1, but the present disclosure is not limited thereto.

The display device 100 can include the hole CH in the substrate 101 and the components on the substrate 101. The hole CH can expose the substrate 101 and the components on the substrate 101. The exposed components on the substrate 101 as well as the substrate 101 can be exposed to physical or chemical damage, including oxygen or moisture from the outside. For example, in the display device 100, a crack can occur in an area corresponding to the hole CH. Additionally, the third metal layer 186 can be exposed to a physical impact or the like in the area corresponding to the hole CH.

When the third metal layer 186 is interrupted by the crack, the third metal layer 186 could be unable to transmit an electrical signal, so that the crack can be sensed.

Additionally, the third metal layer 186 can be disposed at the same layer as the touch electrode 185 and can be made of the same material as the touch electrode 185.

The third metal layer 186 can be disposed in a shape and configured to surround the hole CH, but the present disclosure is not limited thereto. For example, the third metal layer 186 can be formed in a shape with a curve corresponding to the hole CH. For example, the third metal layer 186 can be formed in a shape of two circles, but the present disclosure is not limited thereto.

Further, the third metal layer 186 can be disposed in the first non-display area NA1. For example, the third metal layer 186 can be disposed between the display area AA and the dam DAM. The third metal layer 186 can be a crack sensor, a hole crack sensor, or a crack detector, but the present disclosure is not limited thereto.

The touch protective layer 188 can be disposed on the touch insulating layer 184 throughout the display area AA and the non-display area NA. Further, the touch protective layer 188 can be disposed throughout the first non-display area NA1 and the second non-display area NA2. Additionally, the touch protective layer 188 can cover the third metal layer 186 and can be disposed on the touch insulating layer 184 throughout the first non-display area NA1 and the second non-display area NA2.

A fourth metal layer 192 can be disposed in an area overlapping the dam DAM. For example, the fourth metal layer 192 can be disposed under the dam DAM. However, in another embodiment, the fourth metal layer 192 can be disposed above the dam DAM. Additionally, the fourth metal layer 192 can be disposed on the substrate 101.

The fourth metal layer 192 can be disposed at the same layer as the first gate electrode 122 and can be made of the same material as the first gate electrode 122. For example, the fourth metal layer 192 can be disposed on the second insulating layer 104.

In addition, the fourth metal layer 192 can be an alignment mark necessary for a process of forming the hole CH, but the present disclosure is not limited thereto.

FIG. 5 is an enlarged view of an area B in FIG. 4 according to an embodiment of the present disclosure.

The first metal layer 126′ and the second metal layer 125′ can be disposed in the non-display area NA.

Referring to FIGS. 3 to 5, the first metal layer 126′ can be disposed on the substrate 101. For example, the first metal layer 126′ can be disposed on the buffer layer 102. The first metal layer 126′ can be disposed between the dam DAM and the hole CH. The first metal layer 126′ can be disposed at the same layer as the first light blocking layer 126 in the display area AA and can include the same material as the first light blocking layer 126, but the present disclosure is not limited thereto.

The first insulating layer 103 to the sixth insulating layer 109 can be stacked on the first metal layer 126′, but the present disclosure is not limited thereto.

The first insulating layer 103, the second insulating layer 104, the third insulating layer 105, the fourth insulating layer 106, the fifth insulating layer 108, and the sixth insulating layer 109 can include the first opening OP1.

Additionally, the first insulating layer 103 to the sixth insulating layer 109 can be stacked on the first metal layer 126′, and the first insulating layer 103 to the sixth insulating layer 109 can include the first opening OP1. In addition, the first opening OP1 can be disposed to overlap the first metal layer 126′.

The second metal layer 125′ can be disposed within the first opening OP1. Further, upper portions of the second metal layer 125′ can also be formed on the fifth insulating layer 108 or the sixth insulating layer 109.

The second metal layer 125′ can be connected to the first metal layer 126′ via the first opening OP1. For example, the first metal layer 126′ can be in contact with the second metal layer 125′ within the first opening OP1.

The crack can propagate along the insulating layer. For example, the crack can occur around the hole CH and propagate to the display area AA via the first insulating layer 103, the second insulating layer 104, the third insulating layer 105, the fourth insulating layer 106, the fifth insulating layer 108, or the sixth insulating layer 109 or propagate through multiple insulating layers, or all of the insulating layers to an entirety of the display device 100.

When the first metal layer 126′ and the second metal layer 125′ are connected to each other, the crack propagating along the insulating layer does not propagate via the first metal layer 126′ or the second metal layer 125′ in an area where the first metal layer 126′ and the second metal layer 125′ are connected to each other.

Therefore, the first metal layer 126′ and the second metal layer 125′ of the structure 260 can block the crack propagating along the insulating layer.

The first support layer 111′ can be disposed on the second metal layer 125′. Additionally, the second metal layer 125′ can be disposed between the first support layer 111′ and the insulating layer. Further, the first support layer 111′ can be disposed at the same layer as and include the same material as the first protective layer 111 in the display area AA, but the present disclosure is not limited thereto. For example, the first support layer 111′ can be made of an organic material, but the present disclosure is not limited thereto.

The second support layer 112′ can be disposed on the first support layer 111′. Additionally, the second support layer 112′ can include a protrusion that protrudes into the first support layer 111′. The second support layer 112′ can be disposed at the same layer as and include the same material as the second protective layer 112 in the display area AA, but the present disclosure is not limited thereto. For example, the second support layer 112′ can be made of an organic material, but the present disclosure is not limited thereto.

The structure 260 can further include at least one of the first support layer 111′ and the second support layer 112′, as well as the first metal layer 126′ and the second metal layer 125′. For example, the structure 260 can include the first metal layer 126′, the second metal layer 125′, the first support layer 111′, and the second support layer 112′, but the present disclosure is not limited thereto. In another embodiment, the structure 260 can include the first metal layer 126′, the second metal layer 125′, and the second support layer 112′, but the present disclosure is not limited thereto.

The first support layer 111′ and the second support layer 112′ can be disposed to overlap the first opening OP1. The first opening OP1 can be disposed to overlap the first metal layer 126′ and the second metal layer 125′. The first support layer 111′ and the second support layer 112′ can be disposed to overlap the first metal layer 126′ and the second metal layer 125′. For example, the first support layer 111′ and the second support layer 112′ can be disposed to cover the first metal layer 126′ or the second metal layer 125′.

In addition, the first opening OP1 can be located between the hole CH and the dam DAM. In an embodiment, the opening OP1 can be disposed closer to the hole CH than the dam DAM. However, in another embodiment, the opening OP1 can be disposed closer to the dam DAM than the hole CH.

When the first support layer 111′ and the second support layer 112′ are disposed to cover the first metal layer 126′ or the second metal layer 125′, the first metal layer 126′ or the second metal layer 125′ can be resistant to deformities caused by the crack.

For example, by placing the first metal layer 126′ and the second metal layer 125′ in contact with each other in the first opening OP1, and the first support layer 111′ and the second support layer 112′ on the second metal layer 125′, the crack can be prevented from propagating to the patterns 160 around the structure 260, specifically, the patterns 160 disposed adjacent to the structure 260 in a direction toward the dam DAM. Therefore, the patterns 160 disposed adjacent to the structure 260 in the direction toward the dam DAM can be protected from the crack, which can allow for damage to the patterns 160 by oxygen or moisture from the outside. Because the structure 260 can block the moisture penetration path caused by the crack in an area around the hole CH and protect the patterns 160 from the crack, a reliability and a lifespan of the display device 100 can be improved.

The first support layer 111′ and the second support layer 112′ can include curved portions because of the first opening OP1. The first support layer 111′ and the second support layer 112′ can include the curved portions in an area overlapping the first opening OP1. For example, a concave portion can be disposed at an upper portion of the first support layer 111′ that is located on the second metal layer 125′ that overlaps the first opening OP1, and a convex portion corresponding to the concave portion of the first support layer 111′ can be disposed at a lower portion of the second support layer 112′ that is located on the first support layer 111′.

The first encapsulation layer 171 can be disposed on the second support layer 112′ and the third encapsulation layer 173 can be disposed on the first encapsulation layer 171.

The first encapsulation layer 171 and the third encapsulation layer 173 can include curved portions corresponding to the curved portions of the first support layer 111′ and the second support layer 112′ For example, the first encapsulation layer 171 and the third encapsulation layer 173 can include the curved portions in the area overlapping the first opening OP1. For example, the first encapsulation layer 171 and the third encapsulation layer 173 can include concave portions in the area overlapping the first opening OP1.

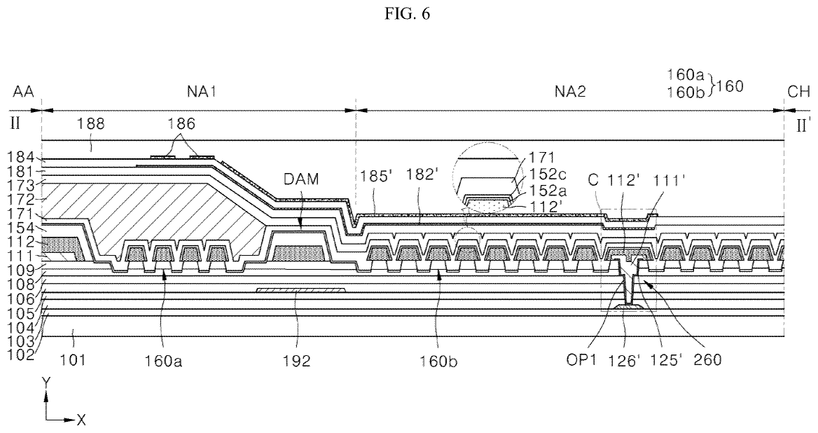

FIG. 6 is a cross-sectional view taken along a line II-II' in FIG. 2 according to another embodiment of the present disclosure.

Some of components shown in FIG. 6 are formed by extending the components of the display area AA shown in FIG. 3 to the non-display area NA, and can be substantially the same as such components. Additionally, some of the components shown in FIG. 6 can be substantially the same as the components shown in FIG. 4.

Hereinafter, the components that are substantially the same as those in FIGS. 3 and 4 will be given the same reference numerals and redundant descriptions thereof will be omitted.

Referring to FIG. 6, the touch buffer layer 181 can be disposed on the third encapsulation layer 173 of the encapsulation portion 170 throughout the display area AA and the non-display area NA. For example, the touch buffer layer 181 can be disposed on the third encapsulation layer 173 throughout the first non-display area NA1 and the second non-display area NA2.

A fifth metal layer 182′ can be disposed on the touch buffer layer 181. The fifth metal layer 182′ can be disposed throughout the first non-display area NA1 and the second non-display area NA2. For example, the fifth metal layer 182′ can extend beyond the dam DAM to the first non-display area NA1, but the present disclosure is not limited thereto. For example, the fifth metal layer 182′ can be disposed only in the second non-display area NA2.

The fifth metal layer 182′ can be disposed at the same layer as the bridge electrode 182 in the display area AA and can include the same material as the bridge electrode 182, but the present disclosure is not limited thereto.

The fifth metal layer 182′ can be disposed to overlap the patterns 160. The fifth metal layer 182′ can be formed to overlap the first metal layer 126′. The fifth metal layer 182′ can be disposed to overlap the first opening OP1. The fifth metal layer 182′ can be disposed to overlap the second metal layer 125′.

The touch insulating layer 184 can be disposed on the touch buffer layer 181 throughout the display area AA and the non-display area NA. For example, the touch insulating layer 184 can be disposed on the touch buffer layer 181 throughout the first non-display area NA1 and the second non-display area NA2. The touch insulating layer 184 can cover the fifth metal layer 182′.

A sixth metal layer 185′ can be disposed on the fifth metal layer 182′. The sixth metal layer 185′ can be disposed on the fifth metal layer 182′ with the touch insulating layer 184 interposed therebetween. The sixth metal layer 185′ can be disposed on the touch insulating layer 184 throughout the first non-display area NA1 and the second non-display area NA2. For example, the sixth metal layer 185′ can extend beyond the dam DAM to the first non-display area NA1, but the present disclosure is not limited thereto. For example, the sixth metal layer 185′ can be disposed only in the second non-display area NA2.

The sixth metal layer 185′ can be disposed at the same layer as the first touch electrode 185 in the display area AA and can include the same material as the touch electrode 185, but the present disclosure is not limited thereto.

The sixth metal layer 185′ can be disposed to overlap the patterns 160. The sixth metal layer 185′ can be disposed to overlap the first metal layer 126′. The sixth metal layer 185′ can be disposed to overlap the first opening OP1. The sixth metal layer 185′ can be disposed to overlap the second metal layer 125′.

The fifth metal layer 182′ and the sixth metal layer 185′ can be disposed to surround the hole CH. For example, the fifth metal layer 182′ and the sixth metal layer 185′ can have a circular shape, but the present disclosure is not limited thereto. In an embodiment, the fifth metal layer 182′ and the sixth metal layer 185′ can entirely surround the hole CH. However, in another embodiment, the fifth metal layer 182′ and the sixth metal layer 185′ can only partially surround the hole CH.

The touch protective layer 188 can be disposed on the touch insulating layer 184 throughout the display area AA and the non-display area NA. For example, the touch protective layer 188 can cover the third metal layer 186 and the sixth metal layer 185′ and can be disposed on the touch insulating layer 184 throughout the first non-display area NA1 and the second non-display area NA2.

The structure 260 can be disposed on the substrate 101. The structure 260 can include the first metal layer 126′ and the second metal layer 125′. At least one of the first support layer 111′ and the second support layer 112′ can be disposed on the second metal layer 125′. The structure 260 can further include at least one of the first support layer 111′ and the second support layer 112′, but the preset disclosure is not limited thereto. At least one of the fifth metal layer 182′ and the sixth metal layer 185′ can be formed on the structure 260. Additionally, in an embodiment, the touch insulating layer 184 can be disposed between the fifth metal layer 182′ and the sixth metal layer 185′.

Effects resulting from the formation of the fifth metal layer 182′ and the sixth metal layer 185′ will be described later.

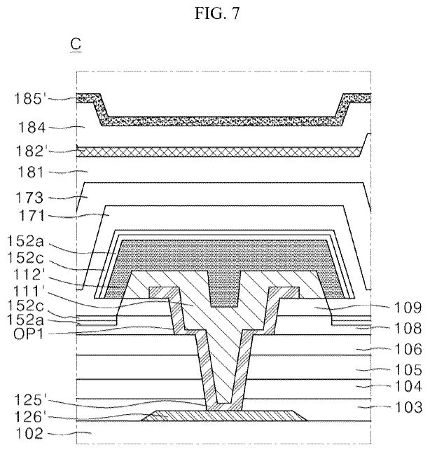

FIG. 7 is an enlarged view of an area C in FIG. 6 according to another embodiment of the present disclosure.

Some of components shown in FIG. 7 can be substantially the same as the components shown in FIGS. 5 and 6. Hereinafter, the components that are substantially the same as those in FIGS. 5 and 6 will be given the same reference numerals and redundant descriptions thereof will be omitted. Further, portions different from those in FIGS. 5 and 6 will be described.

Referring to FIGS. 6 and 7, the touch buffer layer 181 can be disposed on the third encapsulation layer 173. The touch buffer layer 181 can be disposed to extend from the display area AA to the non-display area NA. The fifth metal layer 182′ can be disposed on the touch buffer layer 181. The fifth metal layer 182′ can be disposed to overlap the first opening OP1. In an embodiment, the fifth metal layer 182′ can overlap the entire first opening OP1, however, the present disclosure is not limited thereto. The sixth metal layer 185′ can be disposed on the fifth metal layer 182′. The sixth metal layer 185′ can be formed to overlap the first opening OP1. Additionally, in an embodiment, the sixth metal layer 185′ can overlap the entire first opening OP1, however, the present disclosure is not limited thereto. For example, the sixth metal layer 185′ can correspond to the fifth metal layer 182′ regarding coverage of the first opening OP1.

In another embodiment, the fifth metal layer 182′ and the sixth metal layer 185′ can be disposed to cover the first opening OP1.

The fifth metal layer 182′ and the sixth metal layer 185′ can be configured to cover the patterns 160. As the display device 100 includes the fifth metal layer 182′ and the sixth metal layer 185′, the display device 100 can block the crack propagating via the touch protective layer 188 at a top of the non-display area NA. For example, the crack propagating via the touch protective layer 188 can be blocked by the fifth metal layer 182′ and the sixth metal layer 185′ and the patterns 160 can be protected from the crack, thereby improving the reliability of the display device 100.

The fifth metal layer 182′ and the sixth metal layer 185′ can be described as a crack preventing layer, a shield layer, a protective layer, and the like, but the present disclosure is not limited thereto.

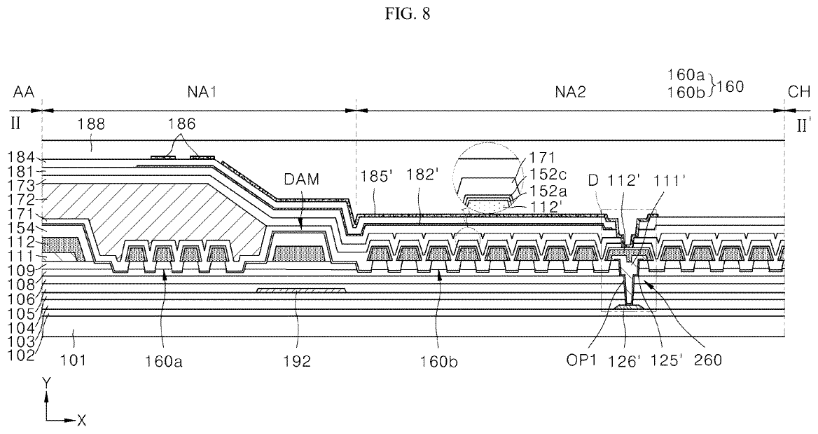

FIG. 8 is a cross-sectional view taken along a line II-II' in FIG. 2 according to another embodiment of the present disclosure.

Some of components shown in FIG. 8 can be formed by extending the components of the display area AA shown in FIG. 3 to the non-display area NA and can be substantially the same as those. Additionally, some of the components shown in FIG. 8 can be substantially the same as the components shown in FIG. 6.

Hereinafter, components that are substantially the same as those in FIGS. 3 and 6 will be given the same reference numerals and redundant descriptions thereof will be omitted.

Referring to FIG. 8, the fifth metal layer 182′ can be disposed on the touch buffer layer 181. The fifth metal layer 182′ can be disposed throughout the first non-display area NA1 and the second non-display area NA2. For example, the fifth metal layer 182′ can only be disposed in the second non-display area NA2.

The fifth metal layer 182′ can be disposed at the same layer as the bridge electrode 182 in the display area AA and can include the same material as the bridge electrode 182, but the present disclosure is not limited thereto.

The fifth metal layer 182′ can be disposed to overlap the patterns 160. In an embodiment, the fifth metal layer 182′ does not overlap the first opening OP1. Additionally, in an embodiment, the fifth metal layer 182′ does not overlap the first metal layer 126′. Further, in an embodiment, the fifth metal layer 182′ does not overlap the second metal layer 125′.

The sixth metal layer 185′ can be disposed on the fifth metal layer 182′. The sixth metal layer 185′ can be disposed on the fifth metal layer 182′ with the touch insulating layer 184 interposed therebetween. The sixth metal layer 185′ can be disposed throughout the first non-display area NA1 and the second non-display area NA2. However, in another embodiment, the sixth metal layer 185′ can only be disposed in the second non-display area NA2.

The sixth metal layer 185′ can be disposed at the same layer as the touch electrode 185 in the display area AA and can include the same material as the touch electrode 185, but the present disclosure is not limited thereto.

The sixth metal layer 185′ can be disposed to overlap the patterns 160. The sixth metal layer 185′ can be disposed to overlap the first metal layer 126′. The sixth metal layer 185′ can be disposed to overlap the first opening OP1. The sixth metal layer 185′ can be disposed to overlap the second metal layer 125′.

The fifth metal layer 182′ and the sixth metal layer 185′ can be disposed to surround the hole CH. For example, the fifth metal layer 182′ and the sixth metal layer 185′ can have a circular shape, but the present disclosure is not limited thereto. In another embodiment, the fifth metal layer 182′ and the sixth metal layer 185′ can only partially surround the hole CH.

The touch protective layer 188 can be disposed on the touch insulating layer 184 throughout the display area AA and the non-display area NA. For example, the touch protective layer 188 can cover the third metal layer 186 and the sixth metal layer 185′ and can be disposed on the touch insulating layer 184 throughout the first non-display area NA1 and the second non-display area NA2.

The structure 260 can be disposed on the substrate 101. The structure 260 can include the first metal layer 126′ and the second metal layer 125′. The first support layer 111′ or the second support layer 112′ can be disposed on the second metal layer 125′. The structure 260 can further include at least one of the first support layer 111′ and the second support layer 112′, but the present disclosure is not limited thereto.

At least one of the first encapsulation layer 171 and the third encapsulation layer 173 can be disposed on the structure 260. The touch buffer layer 181 can be disposed on at least one of the first encapsulation layer 171 and the third encapsulation layer 173. The fifth metal layer 182′ can be disposed on the touch buffer layer 181. The touch insulating layer 184 can be disposed on the fifth metal layer 182′. The sixth metal layer 185′ can be disposed on the touch insulating layer 184.

The first encapsulation layer 171 and the third encapsulation layer 173 can include a second opening OP2. The touch buffer layer 181 and the touch insulating layer 184 can also include the second opening OP2.

The second opening OP2 can be disposed in the first encapsulation layer 171, the third encapsulation layer 173, the touch buffer layer 181, and the touch insulating layer 184. For example, the second opening OP2 can be defined via a process such as etching.

Details regarding the second opening OP2 will be described later.

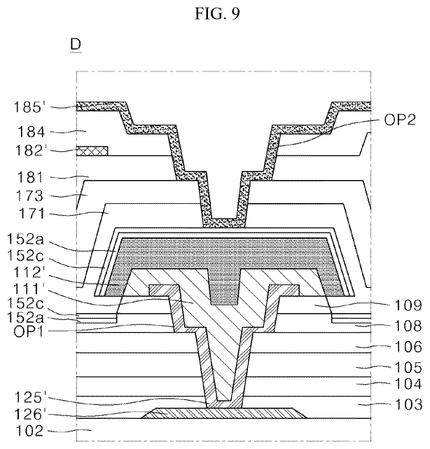

FIG. 9 is an enlarged view of an area D in FIG. 8 according to another embodiment of the present disclosure.

Some of components shown in FIG. 9 can be substantially the same as the components shown in FIGS. 7 and 8. Hereinafter, components that are substantially the same as those in FIGS. 7 and 8 will be given the same reference numerals and redundant descriptions thereof will be omitted. Further, portions different from those in FIGS. 7 and 8 will be described.

Referring to FIGS. 8 and 9, the third encapsulation layer 173 can be disposed on the first encapsulation layer 171. The touch buffer layer 181 can be disposed on the third encapsulation layer 173. The fifth metal layer 182′ can be disposed on the touch buffer layer 181. The touch insulating layer 184 can be disposed on the fifth metal layer 182′. The first encapsulation layer 171, the third encapsulation layer 173, the touch buffer layer 181, and the touch insulating layer 184 can be disposed to extend from the display area AA to the non-display area NA. The sixth metal layer 185′ can be disposed on the touch insulating layer 184. The sixth metal layer 185′ can be disposed to overlap the first opening OP1.

For example, the sixth metal layer 185′ can be disposed to cover the first opening OP1. For example, the fifth metal layer 182′ and the sixth metal layer 185′ can be formed in a shape of surrounding the hole CH, but the present disclosure is not limited thereto. In another embodiment, the fifth metal layer 182′ and the sixth metal layer 185′ can only partially surround the hole CH.

The second opening OP2 can be defined above the first opening OP1. The second opening OP2 can be defined in the first encapsulation layer 171, the third encapsulation layer 173, the touch buffer layer 181, and the touch insulating layer 184. For example, the second opening OP2 can be formed throughout the first encapsulation layer 171, the third encapsulation layer 173, the touch buffer layer 181, and the touch insulating layer 184.

The sixth metal layer 185′ can come into contact with the second light emitting auxiliary layer 152c by the second opening OP2. For example, the second light emitting auxiliary layer 152c can be in direct contact with the sixth metal layer 185′ in an area overlapping the second opening OP2.

The fifth metal layer 182′ and the sixth metal layer 185′ can be described as a crack preventing layer, a shield layer, a protective layer, and the like, but the present disclosure is not limited thereto.

As the second opening OP2 is disposed in the first encapsulation layer 171 and the third encapsulation layer 173, the display device 100 can block the crack propagating via the first encapsulation layer 171 and the third encapsulation layer 173. For example, the second opening OP2 can be formed through some of the components of the encapsulation portion 170. Additionally, the second opening OP2 can be formed in a portion of the encapsulation portion 170. As the second opening OP2 is formed in the touch buffer layer 181 and the touch insulating layer 184, the display device 100 can block the crack propagating via the touch buffer layer 181 and the touch insulating layer 184.

Referring to FIG. 9, the fifth metal layer 182′ does not overlap the second opening OP2, but the display device 100 according to an embodiment of the present disclosure is not limited thereto.

The fifth metal layer 182′ and the sixth metal layer 185′ can be disposed in a shape and configured to cover the patterns 160. As the display device 100 includes the fifth metal layer 182′ and the sixth metal layer 185′, the display device 100 can block the crack propagating via the touch protective layer 188. For example, the crack propagating via the touch protective layer 188 can be blocked and the patterns 160 can be protected from the crack because of the fifth metal layer 182′ and the sixth metal layer 185′, thereby improving the reliability of the display device 100. The display device 100 according to an embodiment of the present disclosure includes the second opening OP2 in the first encapsulation layer 171, the third encapsulation layer 173, the touch buffer layer 181, and the touch insulating layer 184, so that the display device 100 can be prevented from being damaged by the crack propagating via the insulating layer such as the first encapsulation layer 171, the third encapsulation layer 173, and the like on the patterns 160.

For example, the display device 100 according to an embodiment of the present disclosure includes the first opening OP1 and the second opening OP2 and includes the metal layers disposed within the first opening OP1 and the second opening OP2, thereby preventing the damage caused by the crack propagating via the insulating layer.

A display device according to embodiments of the present disclosure can be described as follows.

A display device according to embodiments of the present disclosure can include a substrate including a display area, and a first non-display area and a second non-display area located around the display area, an insulating layer located on the substrate, first patterns located in the first non-display area on the insulating layer, second patterns located in the second non-display area on the insulating layer, and a structure located between the second patterns, the structure includes a first metal layer located between the substrate and the insulating layer, and a second metal layer located on the first metal layer, and the second metal layer is connected to the first metal layer via a first opening defined in the insulating layer.

According to one or more embodiments of the present disclosure, the display device can further include a hole formed in the display area, wherein an optical module is disposed to correspond to the hole, and the second non-display area can be located closer to the hole than the first non-display area.

According to one or more embodiments of the present disclosure, the optical module can include one or more of a distance detection sensor, a facial recognition sensor, and a camera.

According to one or more embodiments of the present disclosure, the first patterns can be disposed to be spaced apart from each other and the second patterns can be disposed to be spaced apart from each other.

According to one or more embodiments of the present disclosure, the structure can further include a support layer located on the second metal layer.

According to one or more embodiments of the present disclosure, the support layer can overlap the first opening.

According to one or more embodiments of the present disclosure, the display device can further include at least one encapsulation layer located on the support layer, a touch insulating layer located on the at least one encapsulation layer, and a third metal layer located on the touch insulating layer.

According to one or more embodiments of the present disclosure, the third metal layer can cover at least one of the structure, the first patterns, and the second patterns.

According to one or more embodiments of the present disclosure, the at least one encapsulation layer and the touch insulating layer can include a second opening overlapping the first opening and a portion of the third metal layer can be disposed within the second opening.

According to one or more embodiments of the present disclosure, the second opening can be formed in a portion of the at least one encapsulation layer.

According to one or more embodiments of the present disclosure, the display device can further include a touch electrode located on the touch insulating layer, and the third metal layer can be located at the same layer as the touch electrode.

According to one or more embodiments of the present disclosure, each of the first patterns and the second patterns can include a lower layer located on the insulating layer, and an upper layer located on the lower layer.

According to one or more embodiments of the present disclosure, the display device can further include a dam located between the first patterns and the second patterns.

According to one or more embodiments of the present disclosure, the substrate can further include a hole defined therein, and the first opening can be located between the hole and the dam.

According to one or more embodiments of the present disclosure, the display device can further include a fourth metal layer located under the dam and overlapping the dam.

According to one or more embodiments of the present disclosure, the display device can further include a light blocking layer located on the substrate, and the light blocking layer can be located at the same layer as the first metal layer.

As described above, the present disclosure is described with reference to illustrative drawings, but the present disclosure is not limited by the embodiments and drawings disclosed in the present disclosure.

It is obvious that various modifications can be made by a person skilled in the art within the scope of the technical idea of the present disclosure.

In addition, even when the effects of the configuration of an embodiment of the present disclosure were not explicitly described and explained earlier while describing an embodiment of the present disclosure, it is natural that the predictable effects of the configuration should also be recognized. Although the embodiments of the present disclosure have been described in more detail with reference to the accompanying drawings, the present disclosure is not necessarily limited to these embodiments, and can be modified in a various manner within the scope of the technical spirit of the present disclosure. Accordingly, the embodiments as disclosed in the present disclosure are intended to describe rather than limit the technical idea of the present disclosure, and the scope of the technical idea of the present disclosure is not limited by these embodiments. Therefore, it should be understood that the embodiments described above are not restrictive but illustrative in all respects.

What is claimed is:

1. A display device comprising:
a substrate including a display area, and a first non-display area and a second non-display area located adjacent to the display area;
an insulating layer located on the substrate;
a plurality of first patterns located in the first non-display area on the insulating layer;
a plurality of second patterns located in the second non-display area on the insulating layer; and
a structure located between the plurality of second patterns,
wherein the structure includes:
a first metal layer located between the substrate and the insulating layer; and
a second metal layer located on the first metal layer, and
wherein the second metal layer is connected to the first metal layer via a first opening defined in the insulating layer.

2. The display device of claim 1, further comprising a hole formed in the display area, wherein an optical module is disposed to correspond to the hole, and
wherein the second non-display area is located closer to the hole than the first non-display area.

3. The display device of claim 2, wherein the optical module includes at least one of a distance detection sensor, a facial recognition sensor, and a camera.

4. The display device of claim 1, wherein the plurality of first patterns are disposed to be spaced apart from each other, and
wherein the plurality of second patterns are disposed to be spaced apart from each other.

5. The display device of claim 1, wherein the structure further includes a support layer located on the second metal layer.

6. The display device of claim 5, wherein the support layer overlaps the first opening.

7. The display device of claim 5, further comprising:
at least one encapsulation layer located on the support layer;
a touch insulating layer located on the at least one encapsulation layer; and
a third metal layer located on the touch insulating layer.

8. The display device of claim 7, wherein the third metal layer covers at least one of the structure, the plurality of first patterns, and the plurality of second patterns.

9. The display device of claim 7, wherein the at least one encapsulation layer and the touch insulating layer include a second opening overlapping the first opening, and
wherein a portion of the third metal layer is disposed within the second opening.

10. The display device of claim 9, wherein the second opening is formed in a portion of the at least one encapsulation layer.

11. The display device of claim 7, further comprising a touch electrode located on the touch insulating layer,
wherein the third metal layer is located at a same layer as the touch electrode.

12. The display device of claim 1, wherein each of the plurality first patterns and the plurality second patterns includes:
a lower layer located on the insulating layer; and
an upper layer located on the lower layer.

13. The display device of claim 1, further comprising a dam located between the plurality of first patterns and the plurality of second patterns.

14. The display device of claim 13, wherein the substrate further includes a hole defined therein, and
wherein the first opening is located between the hole and the dam.

15. The display device of claim 13, further comprising a fourth metal layer located under the dam and configured to overlap the dam in a lengthwise direction.

16. The display device of claim 1, further comprising a light blocking layer located on the substrate,
wherein the light blocking layer is located at a same layer as the first metal layer.

17. A display device, comprising:
a display area, a first non-display area, and a second non-display area all located on a substrate;
at least one insulating layer located on the substrate;
a plurality of first patterns located in the first non-display area on the at least one insulating layer;
a plurality of second patterns located in the second non-display area on the at least one insulating layer; and
a structure located between the plurality of second patterns,
wherein the structure includes:
a first opening disposed in the at least one insulating layer;
a metal layer disposed in the first opening,
wherein a portion of the metal layer is disposed on an upper portion of the at least one insulating layer.

18. The display device of claim 17, wherein the structure further comprises a first support layer disposed on the metal layer and disposed in the first opening.

19. The display device of claim 18, further comprising:
a second opening overlapping the first opening;
a second metal layer disposed in the second opening; and
a second support layer disposed on the first support layer,
wherein the second support layer is disposed between the first opening and the second opening.

20. The display device of claim 19, wherein the second support layer comprises a protrusion that protrudes into the first opening.

21. The display device of claim 17, further comprising a dam,
wherein the dam is located between the plurality of first patterns and the plurality of second patterns.

22. The display device of claim 17, further comprising a hole disposed in the substrate and the at least one insulating layer,
wherein the hole is disposed on a side of the structure away from the plurality of first patterns.

23. The display device of claim 22, wherein the structure is configured to surround the hole.
